(19) United States
(12) Patent Application Publication
(10) Pub. No.: US 2026/0362888 A1
(43) Pub. Date: Nov. 12, 2026

(54) LIGHT EMITTING DEVICE AND LIGHT EMITTING SYSTEM INCLUDING THE SAME

(71) Applicant: SEOUL SEMICONDUCTOR CO., LTD., Ansan-si (KR)

(72) Inventor: MyungJin KIM, Ansan-si (KR)

(73) Assignee: SEOUL SEMICONDUCTOR CO., LTD., Ansan-si (KR)

(21) Appl. No.: 19/670,100

(22) Filed: May 7, 2026

Related U.S. Application Data
(60) Provisional application No. 63/804,035, filed on May 12, 2025.

(51) Int. Cl. H10H 29/855; G02F 1/1334; G02F 1/137; H10H 29/853

(52) U.S. Cl. CPC H10H 29/855; G02F 1/1334; G02F 1/137; H10H 29/853

(57) ABSTRACT

A light emitting device includes: a substrate; a light emitting element disposed on the substrate to generate light; a molding layer disposed on the substrate to cover the light emitting element; and an aperture group layer disposed on the molding layer and emitting the light of the light emitting element to an outside. The aperture group layer includes: a conductive layer applied with an electrical signal; and an aperture layer configured to be in a first state of transmitting light when the electrical signal is applied to the conductive layer, and to be in a second state of scattering light when the electrical signal is not applied to the conductive layer. Luminous intensity of the light emitted from the aperture group layer in the first state is greater than luminous intensity of the light emitted from the aperture group layer in the second state.

### TECHNICAL FIELD

The present disclosure relates to a light emitting device and a light emitting system including the same.

### BACKGROUND OF THE INVENTION

Recently, a light emitting diode (LED) has been widely used.

The light emitting diode converts an electrical signal into a form of light such as an infrared ray, a visible ray, or an ultraviolet ray using characteristics of a compound semiconductor.

As light efficiency of the light emitting element increases, the light emitting element is applied to various fields including a display device, a lighting device, a vehicle, and the like.

Recently, a need for a light emitting device irradiating light displaying various information is increasing.

### SUMMARY OF THE INVENTION

Embodiments of the present disclosure provide a light emitting device capable of being transparent or opaque and a light emitting system including the same.

Furthermore, embodiments of the present disclosure provide a light emitting device capable of exhibiting the same color as a surrounding color and a light emitting system including the same.

In accordance with a first aspect of the present disclosure, there is provided a light emitting device including: a substrate; a light emitting element disposed on the substrate to generate light; a molding layer disposed on the substrate to cover the light emitting element; and an aperture group layer disposed on the molding layer and emitting the light of the light emitting element to an outside, wherein the aperture group layer includes: a conductive layer applied with an electrical signal; and an aperture layer configured to be in a first state of transmitting light when the electrical signal is applied to the conductive layer, and to be in a second state of scattering light when the electrical signal is not applied to the conductive layer, and wherein luminous intensity of the light emitted from the aperture group layer in the first state is greater than luminous intensity of the light emitted from the aperture group layer in the second state.

Further, the luminous intensity of the light emitted from the aperture group layer in the second state may be 50% or less of the luminous intensity of the light emitted from the aperture group layer in the first state.

Further, a color of the light emitted from the aperture group layer in the first state and a color of the light emitted from the aperture group layer in the second state may be different from each other.

Further, the light emitting element may include: an element electrode layer electrically connected to the substrate; and a light emitting layer emitting light when electricity is applied to the element electrode layer. A number of conductive layers may be greater than a number of element electrode layers.

Further, the substrate may be configured to transmit light, and when the aperture layer is in the first state, a wavelength deviation between a peak wavelength of the light emitted from the aperture group layer and a peak wavelength of the light transmitted through the substrate may be within 1%.

Further, the substrate may be configured to transmit light, when the aperture layer is in the second state, the luminous intensity of the light emitted from the aperture group layer may be smaller than luminous intensity of the light transmitted through the substrate.

Further, the conductive layer may include a plurality of conductive layers, the aperture layer may be disposed between the plurality of conductive layers, the aperture group layer may further include a plurality of support layers covering the plurality of conductive layers such that the plurality of conductive layers and the aperture layer may be disposed inside, and one of the plurality of support layers may be in contact with the molding layer.

Further, a thickness of each of the plurality of support layers may be greater than a thickness of each of the plurality of conductive layers and a thickness of the aperture layer, and the thickness of the aperture layer may be greater than the thickness of each of the plurality of conductive layers.

Further, a refractive index of the conductive layer may be greater than a refractive index of the support layer.

Further, the aperture layer may include: a polymer layer supported by the conductive layer; and a plurality of liquid crystal molecules disposed in the polymer layer, when the aperture layer is in the first state, a refractive index of the plurality of liquid crystal molecules may be equal to the refractive index of the polymer layer, and when the aperture layer is in the second state, the refractive index of the plurality of liquid crystal molecules may be different from the refractive index of the polymer layer.

Further, a refractive index of the conductive layer may be greater than the refractive index of the polymer layer.

Further, the aperture layer may further include: a plurality of partition walls disposed in the polymer layer to partition the polymer layer into a plurality of polymer regions.

Further, the light emitting element may include a plurality of the light emitting elements, and the plurality of light emitting elements may be disposed directly below the plurality of polymer regions.

Further, the light emitting element may include a plurality of the light emitting elements, and a separation distance between the plurality of partition walls may be greater than a separation distance between the plurality of light emitting elements.

Further, the plurality of partition walls may include: a plurality of first partition walls extending in one direction and disposed to be spaced apart from each other in another direction intersecting the one direction; and a plurality of second partition walls extending in the other direction and disposed to be spaced apart from each other in the one direction.

In accordance with a second aspect of the present disclosure, there is provided a light emitting device including: a substrate; a light emitting element disposed on the substrate to generate light; a molding layer disposed on the substrate to cover the light emitting element; and an aperture group layer stacked on the molding layer and emitting the light of the light emitting element, wherein the aperture group layer includes: a conductive layer applied with an electrical signal; and an aperture layer configured to be in a first state of transmitting light when the electrical signal is applied to the conductive layer, and to be in a second state of scattering light when the electrical signal is not applied to the conductive layer, and wherein brightness of the light emitted from the aperture group layer when the aperture layer is in the first state is greater than brightness of the light emitted from the aperture group layer when the aperture layer is in the second state.

Further, the substrate may be configured to transmit light, and when the aperture layer is in the first state, a wavelength deviation between a peak wavelength of the light emitted from the aperture group layer and a peak wavelength of the light transmitted through the substrate may be within 1%.

In accordance with a third aspect of the present disclosure, there is provided a light emitting device including: a substrate; a light emitting element disposed on the substrate to generate light; a molding layer disposed on the substrate to cover the light emitting element; and an aperture group layer stacked on the molding layer and emitting the light of the light emitting element, wherein the aperture group layer includes: a conductive layer applied with an electrical signal; and an aperture layer configured to be in a first state of transmitting light when the electrical signal is applied to the conductive layer, and to be in a second state of scattering light when the electrical signal is not applied to the conductive layer, and wherein a directivity angle of the light emitted from the aperture group layer when the aperture layer is in the first state is smaller than a directivity angle of the light emitted from the aperture group layer when the aperture layer is in the second state.

Further, the substrate may be configured to transmit light, and when the aperture layer is in the first state, a wavelength deviation between a peak wavelength of the light emitted from the aperture group layer and a peak wavelength of the light transmitted through the substrate may be within 1%.

Further, a color of the light emitted from the aperture group layer in the first state and a color of the light emitted from the aperture group layer in the second state may be different from each other.

According to an embodiment of the present disclosure, light is transmitted through an aperture group layer without being scattered when a current is applied to an aperture layer.

Furthermore, according to an embodiment of the present disclosure, when a current is not applied to the aperture layer, the aperture group layer is formed opaquely such that an inside of the light emitting device is blocked from being viewed from an outside.

Furthermore, according to an embodiment of the present disclosure, when a current is not applied to the aperture layer, the aperture group layer is formed in the same color as a surrounding color.

Furthermore, according to an embodiment of the present disclosure, external light is scattered since a refractive index of a conductive layer is greater than a refractive index of a support layer and a refractive index of a polymer layer.

Furthermore, according to an embodiment of the present disclosure, a plurality of liquid crystal molecules are uniformly disposed in the polymer layer by a plurality of partition walls.

### BRIEF DESCRIPTION OF THE DRAWINGS

FIG. 1 is a perspective view illustrating a first example of a light emitting system according to a first embodiment of the present disclosure.

FIG. 2 is a perspective view illustrating a second example of the light emitting system according to the first embodiment of the present disclosure.

FIG. 3 is a view illustrating a light emitting device included in the light emitting system according to the first embodiment of the present disclosure.

FIG. 4 is a view illustrating a light emitting device included in a light emitting system according to a second embodiment of the present disclosure.

FIG. 5 is a view illustrating a plurality of partition walls of the light emitting device of FIG. 4 viewed from above.

FIG. 6 is a view illustrating a light emitting device included in a light emitting system according to a third embodiment of the present disclosure.

FIG. 7 is a view illustrating a light emitting device included in a light emitting system according to a fourth embodiment of the present disclosure.

FIG. 8 is a view illustrating a light emitting device included in a light emitting system according to a fifth embodiment of the present disclosure.

FIG. 9 is a view illustrating a light emitting device included in a light emitting system according to a sixth embodiment of the present disclosure.

### DETAILED DESCRIPTION OF THE INVENTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z – axes, and may be interpreted in a broader sense. For example, the DR1-axis, the D2R-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting device 10 according to the first embodiment of the present disclosure and a light emitting system 1 including the same will be described.

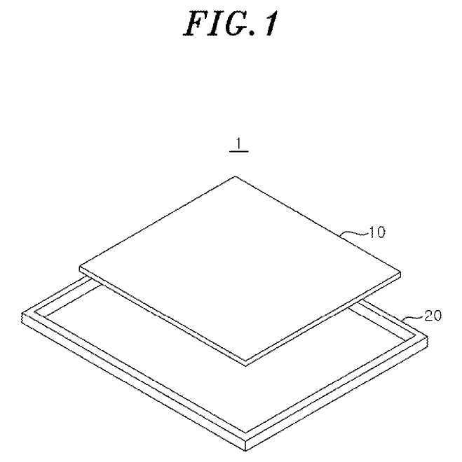

The light emitting system 1 illustrated in FIG. 1 is a display device, and may include one or more light emitting devices 10 including a plurality of light emitting elements 200 to be described later. The light emitting system 1 may display information, and may output various visual contents. The light emitting system 1 may be applied to a signage, an AR device, a VR device, a vehicle display device, and the like.

A frame 20 may be disposed on an outside of the light emitting system 1. Electrical wiring may be added to one region of the frame 20 such that the light emitting system 1 is electrically connected to an external power source and an operation of the light emitting system 1 is controlled according to an electrical signal. Furthermore, the light emitting system 1 may be controlled according to an external signal, and thus may be driven in various ways.

The frame 20 may serve to reinforce strength of the light emitting system 1, and may be made of a material having higher strength than a substrate 100 to be described later of the light emitting device 10. The frame 20 may also be utilized as a structural support connecting different light emitting devices 10. Various materials may be used for the frame 20 according to mechanical strength, workability, and the like. In one example, the frame 20 may include a metal material such as aluminum, stainless steel, copper, and the like. In another example, the frame 20 may include a polymer material such as polycarbonate, acrylic, polyamide, and ABS, or a carbon fiber reinforced plastic, a glass fiber reinforced plastic, and a ceramic.

Furthermore, the frame 20 may be manufactured in a form surrounding the light emitting device 10 to reinforce the strength of the light emitting system 1, but is not limited thereto. The frame 20 may be disposed only on one surface of the light emitting device 10 to reduce an area of the light emitting system 1.

Furthermore, the light emitting system 1 may further include a diffusion plate and a plurality of optical sheets. A display panel may be disposed on one surface of at least one of the plurality of optical sheets. The display panel is not particularly limited. For example, the display panel may be a liquid crystal display panel including a liquid crystal layer. Furthermore, a gate driving PCB supplying a driving signal to a gate line and a data driving PCB supplying a driving signal to a data line may be provided at an edge of the display panel.

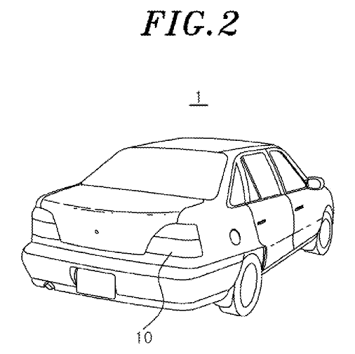

Further referring to FIG. 2, the light emitting system 1 may be configured as a vehicle display or a vehicle light source. In the light emitting system 1 requiring driving by region like a smart headlamp, clear projection image implementation is possible by reducing cross-talk for each projection region. The light emitting device 10 may be included in a taillight, a headlight, a rear lamp, a tail lamp, and the like. Furthermore, the light emitting device 10 mounted on a vehicle may emit red-based light, yellow-based light, or white-based light to display information such as a stop signal or characters to the outside. The light emitting device 10 may be included in a vehicle interior display or the like to display information.

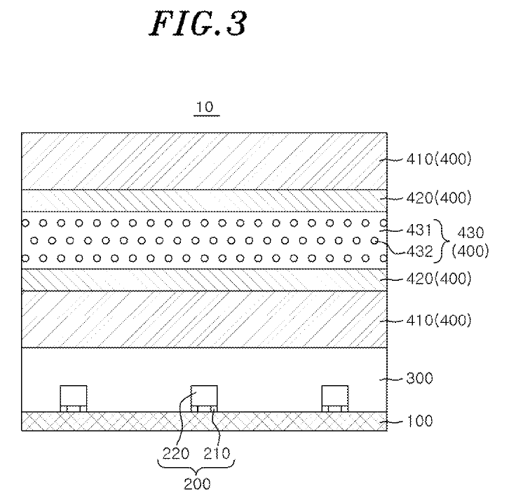

Further referring to FIG. 3, the light emitting device 10 may include a substrate 100, a light emitting element 200, a molding layer 300, and an aperture group layer 400.

The light emitting element 200 may be disposed on the substrate 100. For example, the substrate 100 may be a printed circuit board (PCB) on which an electric circuit is printed. Furthermore, the substrate 100 may be a thin-film transistor (TFT) backplane. The substrate 100 may be made of a metal material having thermal conductivity, such as Cu, Al, and the like. However, this is merely an example, and the substrate 100 may include one or more insulating materials such as FR1, CEM-1, FR-4, PMMA, PCT, and PPA, thereby preventing short circuits between respective circuits. Here, FR1 is a material formed by stacking copper foil and laminate paper, and CEM-1 is a material formed by sequentially stacking copper foil, glass fiber fabric, laminate paper, and glass fiber fabric. Furthermore, FR-4 is a material formed by stacking copper foil and glass fiber woven or glass fiber fabric. Furthermore, the substrate 100 may include a ceramic such as alumina (Al₂O₃), aluminum nitride (AlN), or Zirconia Toughened Alumina (ZTA). Furthermore, the substrate 100 may transmit light.

The light emitting element 200 may be disposed on the substrate 100 to generate light. For example, the light emitting element 200 may generate blue, green, red, white light, UV light, and the like. The light emitting element 200 may be electrically connected to the substrate 100 and may generate light by receiving electricity supplied from the outside through the electric circuit. The light emitting element 200 may include an element electrode layer 210 and a light emitting layer 220.

The element electrode layer 210 may be electrically connected to the substrate 100 and the light emitting layer 220. In other words, the element electrode layer 210 may be electrically connected to a first conductivity-type semiconductor layer or a second conductivity-type semiconductor layer. The light emitting layer 220 may generate light by the electricity applied from the element electrode layer 210. For example, the element electrode layer 210 may include Sn, Ag, Au, Ni, Ti, Al, and the like.

The light emitting layer 220 may generate light. The light emitting layer 220 may be electrically connected to the element electrode layer 210. The light emitting layer 220 may include the first conductivity-type semiconductor layer, an active layer, and the second conductivity-type semiconductor layer.

The first conductivity-type semiconductor layer is a semiconductor layer having a polarity opposite to that of the second conductivity-type semiconductor layer. The first conductivity-type semiconductor layer may include n-type impurities (for example, at least one of Si, Ge, and Sn). In this case, the first conductivity-type semiconductor layer may be an n-type semiconductor layer. However, this is merely an example, and the first conductivity-type semiconductor layer may include p-type impurities.

The active layer may be stacked on the first conductivity-type semiconductor layer. In other words, the active layer may be located between the first conductivity-type semiconductor layer and the second conductivity-type semiconductor layer. Furthermore, the active layer may be disposed to be biased toward one side from a center of a thickness of the light emitting element. By the active layer, a length of the first conductivity-type semiconductor layer in an up and down direction may be greater than a length of the second conductivity-type semiconductor layer in the up and down direction.

The second conductivity-type semiconductor layer may be stacked on the active layer. The second conductivity-type semiconductor layer may include p-type impurities (for example, at least one of Mg, Sr, and Ba), and in this case, the second conductivity-type semiconductor layer may be a p-type semiconductor layer. However, this is merely an example, and the second conductivity-type semiconductor layer may include n-type impurities. Light generated in the active layer may pass through the second conductivity-type semiconductor layer to be emitted to the outside.

The molding layer 300 may be disposed on the substrate 100 to cover the light emitting element 200. The light generated by the light emitting element 200 may be transmitted through the molding layer 300. The molding layer 300 may prevent the light emitting element 200 from being detached or peeled off from the substrate 100. The molding layer 300 may include a material or a configuration for diffusing light generated by the light emitting element 200 or changing a wavelength of the light.

The aperture group layer 400 may be disposed on the molding layer 300. Furthermore, the aperture group layer 400 may emit the light transmitted through the molding layer 300 to the outside. The aperture group layer 400 may be disposed on the molding layer 300 to control transmittance of the light emitted from the molding layer 300. Furthermore, the aperture group layer 400 may be electrically connected to an external electrical signal (current or voltage). The aperture group layer 400 may be formed transparently or opaquely by a voltage or a current applied from the outside such that transparency or transmittance is controlled. In other words, when a current is not applied, the aperture group layer 400 may reduce a color of an electrode pattern of the substrate 100 on which the light emitting device 10 is installed or the molding layer 300 covering the light emitting element 200, or an amount by which the light emitted from the light emitting element 200 is exposed to the outside. When a current is applied, the aperture group layer 400 may allow the light generated by the light emitting element 200 to be emitted to the outside.

The aperture group layer 400 may include a support layer 410, a conductive layer 420, and an aperture layer 430.

The support layer 410 may be disposed on the molding layer 300 to support the conductive layer 420 and the aperture layer 430. Furthermore, the support layer 410 may protect the conductive layer 420 and the aperture layer 430. For example, the support layer 410 may be a film or substrate made of polyethylene terephthalate (PET). Furthermore, a plurality of support layers 410 may be formed to cover the conductive layer 420 and the aperture layer 430. That is, the conductive layer 420 and the aperture layer 430 may be disposed between the plurality of support layers 410. A thickness of each of the plurality of support layers 410 may be greater than a thickness of the conductive layer 420 and a thickness of the aperture layer 430. Therefore, current of the conductive layer 420 may be prevented from traveling in a direction of the light emitting element 200. The thickness may be a length in the up and down direction.

The conductive layer 420 applied with electricity may be disposed between the plurality of support layers 410. The conductive layer 420 may be a transparent conductive oxide (TCO). The conductive layer 420 has high electrical conductivity and transparency at the same time and may be disposed on the support layer 410 in a thin film form. Furthermore, a plurality of conductive layers 420 may be formed to support the aperture layer 430. In other words, the aperture layer 430 may be disposed between the plurality of conductive layers 420. A thickness of each of the plurality of conductive layers 420 may be smaller than the thickness of the aperture layer 430. When the thickness of each of the plurality of conductive layers 420 is less than a thickness of the aperture layer 430, a supply speed of a voltage or a current supplied to the plurality of conductive layers 420 increases such that a reaction speed of the aperture layer 430 according to the electrical signal increases and fine transmittance control is possible. Furthermore, the thickness of each of the plurality of conductive layers 420 may be greater than a thickness of the element electrode layer 210.

A refractive index of each of the plurality of conductive layers 420 may be greater than a refractive index of each of the plurality of support layers 410. Furthermore, the refractive index of each of the plurality of conductive layers 420 may be greater than a refractive index of a polymer layer 431 to be described later. Therefore, the plurality of conductive layers 420 may scatter external light to block the plurality of light emitting elements 200 from being viewed.

The aperture layer 430 is disposed between the plurality of conductive layers 420, and may be placed in a first state of transmitting light when electricity is applied to the plurality of conductive layers 420. The first state may be a transparent or transmissive state. Furthermore, the aperture layer 430 may be placed in a second state of scattering light when electricity is not applied to the plurality of conductive layers 420. For example, the aperture layer 430 may be a polymer dispersed liquid crystal (PDLC).

Luminous intensity of the light emitted from the aperture group layer 400 when the aperture layer 430 is in the first state may be greater than luminous intensity of the light emitted from the aperture group layer 400 when the aperture layer 430 is in the second state. In other words, the luminous intensity of the light emitted from the aperture group layer 400 in the second state may be 50% or less compared to the luminous intensity of the light emitted from the aperture group layer 400 in the first state. Brightness of the light emitted from the aperture group layer 400 when the aperture layer 430 is in the first state may be greater than brightness of the light emitted from the aperture group layer 400 when the aperture layer 430 is in the second state. In other words, an L-value (lightness value) of the light emitted from the aperture group layer 400 may be greater when the aperture layer 430 is in the first state than when the aperture layer 430 is in the second state.

A directivity angle of the light emitted from the aperture group layer 400 when the aperture layer 430 is in the first state may be smaller than a directivity angle of the light emitted from the aperture group layer 400 when the aperture layer 430 is in the second state. In other words, when the aperture layer 430 is in the second state, light may be scattered while being transmitted through the aperture group layer 400. Therefore, the luminous intensity of the light emitted from the aperture group layer 400 may be lowered by lowering concentration of light distribution.

When the aperture layer 430 is in the first state, a wavelength deviation between a peak wavelength of the light emitted from the aperture group layer 400 and a peak wavelength of the light transmitted through the substrate 100 may be within 1%. Furthermore, when the aperture layer 430 is in the second state, the luminous intensity of the light emitted from the aperture group layer 400 may be smaller than luminous intensity of the light transmitted through the substrate 100. Therefore, the luminous intensity may be controlled to be different depending on a direction.

The aperture layer 430 may include a polymer layer 431 and a plurality of liquid crystal molecules 432.

The polymer layer 431 may be disposed between the plurality of conductive layers 420 to support the plurality of liquid crystal molecules 432. The polymer layer 431 may be named a polymer layer. The polymer layer 431 may include at least one selected from the group consisting of NOA65, NOA81 (Norland Optical Adhesive), TMPTA (Trimethylolpropane triacrylate), Bis-GMA, UDMA, or acrylate. The polymer layer 431 may have a predetermined refractive index. The refractive index of the polymer layer 431 may be smaller than the refractive index of each of the plurality of conductive layers 420. A thickness of the polymer layer 431 may be greater than the thickness of each of the plurality of conductive layers 420. Therefore, external light incident on the plurality of conductive layers 420 is interfered with or reflected to be annihilated, thereby allowing the light generated by the light emitting element 200 to be emitted more clearly.

The plurality of liquid crystal molecules 432 may be disposed inside the polymer layer 431. In the first state, the plurality of liquid crystal molecules 432 may be aligned along a direction of an electric field. In the first state, a refractive index of the plurality of liquid crystal molecules 432 is equal to the refractive index of the polymer layer 431, such that light scattering may be reduced. By the plurality of liquid crystal molecules 432 in the first state, the light generated by the light emitting element 200 may be transmitted through the aperture group layer 400 while traveling straight without being scattered in the aperture layer 430.

Furthermore, the plurality of liquid crystal molecules 432 may be disorderly disposed in the polymer layer 431 in the second state. In other words, in the second state, the plurality of liquid crystal molecules 432 may be placed in a direction different from the electric field direction aligned in the first state. In the second state, the refractive index of the plurality of liquid crystal molecules 432 may be different from the refractive index of the polymer layer 431. Furthermore, refractive indices according to phases and thicknesses of the plurality of liquid crystal molecules 432 disposed disorderly are diversified, such that the light generated by the light emitting element 200 may be scattered in the aperture layer 430 by the plurality of liquid crystal molecules 432 in the second state.

A color material may be included in the plurality of liquid crystal molecules 432, and the color material may be a dye or a pigment. The color material may be controlled such that a color of the aperture group layer 400 in the first state and a color in the second state are different from each other. Due to the color material of the plurality of liquid crystal molecules 432, a color of the light emitted from the aperture group layer 400 in the first state and a color of the light emitted from the aperture group layer 400 in the second state may be different from each other.

Hereinafter, actions and effects of the light emitting device 10 according to the first embodiment of the present disclosure and the light emitting system 1 including the same will be described.

When the aperture layer 430 of the light emitting device 10 is in the first state, the light generated by the light emitting element 200 may be transmitted through the molding layer 300 and the aperture group layer 400. When the aperture layer 430 is in the first state, the light generated by the light emitting element 200 may be transmitted without being scattered in the aperture group layer 400. When the aperture layer 430 of the light emitting device 10 is in the second state, the light generated by the light emitting element 200 may be scattered in the aperture group layer 400.

When a current is applied to the aperture layer 430, light may be transmitted through the aperture group layer 400 without being scattered, such that light efficiency may increase.

Furthermore, when a current is not applied to the aperture layer 430, the aperture group layer 400 becomes opaque, thereby blocking an inside of the light emitting device 10 from being viewed from the outside.

Furthermore, when a current is not applied to the aperture layer 430, the aperture group layer 400 may be capable of exhibiting a color.

Furthermore, since the refractive index of each of the plurality of conductive layers 420 may be greater than the refractive index of each of the plurality of support layers 410 and the refractive index of the polymer layer 431, external light may be scattered more effectively.

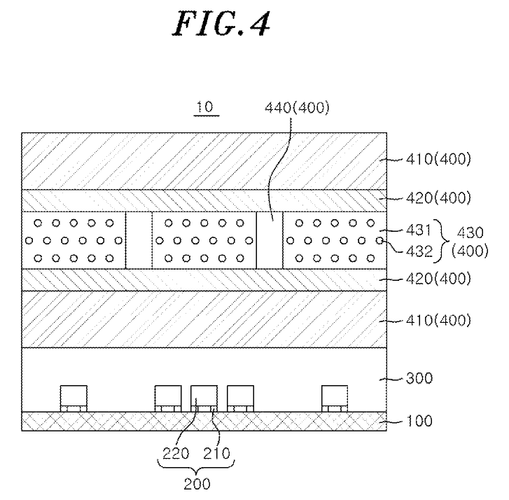

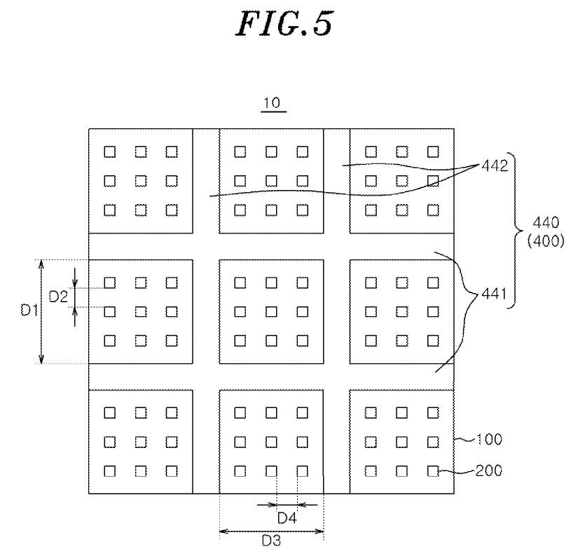

Hereinafter, a light emitting device 10 according to a second embodiment of the present disclosure and a light emitting system 1 including the same will be described with reference to FIGS. 4 and 5. In describing the second embodiment, there is a difference in that the aperture group layer 400 further includes a plurality of partition walls 440, and the description will focus on such differences.

The plurality of partition walls 440 may be disposed in the polymer layer 431 to partition the polymer layer 431 into a plurality of polymer regions. Upper ends and lower ends of the plurality of partition walls 440 may be in contact with the plurality of conductive layers 420. The plurality of liquid crystal molecules 432 may be disposed in each of the plurality of polymer regions. The plurality of partition walls 440 may include a plurality of first partition walls 441 and a plurality of second partition walls 442. By the plurality of partition walls 440, the plurality of light emitting elements 200 may be disposed in regions directly below each of the polymer regions.

The plurality of first partition walls 441 may extend in one direction and be disposed to be spaced apart from each other in another direction intersecting the one direction. Furthermore, a first separation distance D1 between the plurality of first partition walls 441 may be greater than a second separation distance D2 between at least two light emitting elements 200 disposed between the plurality of first partition walls 441. The first separation distance D1 and the second separation distance D2 may be distances spaced apart in the other direction.

Furthermore, the plurality of second partition walls 442 may extend in the other direction and be disposed to be spaced apart from each other in the one direction. The plurality of second partition walls 442 may be connected to the plurality of first partition walls 441 while extending in the other direction. Furthermore, a third separation distance D3 between the plurality of second partition walls 442 may be greater than a fourth separation distance D4 between at least two light emitting elements 200 disposed between the plurality of second partition walls 442. The third separation distance D3 and the fourth separation distance D4 may be distances spaced apart in the one direction.

Hereinafter, operations and effects of the light emitting device 10 according to the second embodiment of the present disclosure and the light emitting system 1 including the same will be described.

Light generated from the plurality of light emitting elements 200 may be emitted to the outside while being transmitted through the plurality of polymer regions partitioned by the plurality of partition walls 440.

By the plurality of partition walls 440, the plurality of liquid crystal molecules 432 may be uniformly disposed in the polymer layer 431.

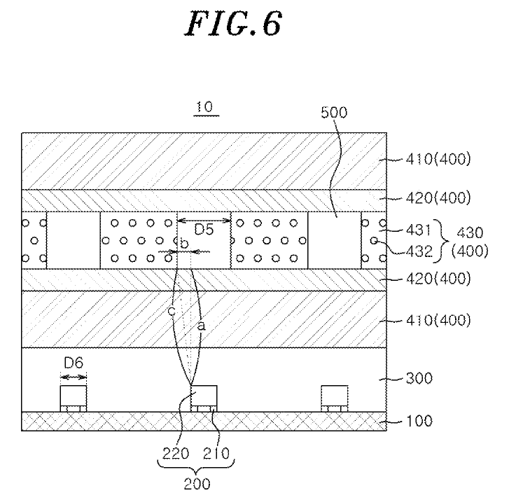

Hereinafter, a light emitting device 10 according to a third embodiment of the present disclosure and a light emitting system 1 including the same will be described with reference to FIG. 6. In describing the third embodiment, there is a difference in that the aperture group layer 400 further includes a plurality of openings 500, and the description will focus on this difference.

The aperture group layer 400 may include an opening 500. The opening 500 may be formed in the aperture layer 430. Furthermore, the opening 500 may overlap the light emitting element 200 in a thickness direction. In other words, when viewed in the up and down direction, an edge of the light emitting element 200 may be located inside the opening 500.

The liquid crystal molecules 432 may be disposed around the opening 500. Furthermore, a plurality of openings 500 may be formed and disposed to be spaced apart from each other. In other words, the liquid crystal molecules 432 may be disposed between the plurality of openings 500. Light transmittance of the opening 500 and light transmittance between the plurality of openings 500 may be different from each other. Transmittance of light emitted through the opening 500 may be higher than transmittance of light emitted between the plurality of openings 500. When viewed from above, a shape of the opening 500 may be circular or polygonal. An upper surface or a lower surface of the opening 500 may be covered by the plurality of conductive layers 420.

A width D5 of the opening 500 may be greater than a width D6 of the light emitting element 200 when viewed in cross-section. A vertical distance from an upper edge of the light emitting element 200 to a lower surface of the opening 500 may be a, and a distance in a horizontal direction from the upper edge of the light emitting element 200 to a lower edge of the opening 500 may be b. Furthermore, a distance from the upper edge of the light emitting element 200 to the lower edge of the opening 500 may be c. The distance a may be greater than b, and c may be greater than a. The distance b may be greater than a. A ratio of b to c may be from 0.5 to 1. A ratio of a to c may be from 0.1 to 0.866.

Hereinafter, operations and effects of the light emitting device 10 according to the third embodiment of the present disclosure and the light emitting system 1 including the same will be described.

Visibility of light generated from the light emitting element 200 of the light emitting device 10 according to the third embodiment of the present disclosure may be increased.

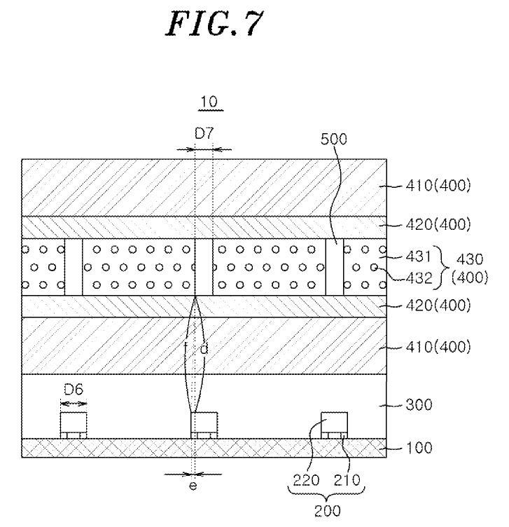

Hereinafter, a light emitting device 10 according to a fourth embodiment of the present disclosure and a light emitting system 1 including the same will be described with reference to FIG. 7. In describing the fourth embodiment, there is a difference in that a size of the plurality of openings 500 may be formed differently from the above-described third embodiment, and the description will focus on this difference.

Referring to FIG. 7, a width D7 of the opening 500 may be smaller than the width D6 of the light emitting element 200 when viewed in cross-section. A vertical distance from an upper edge of the opening 500 to a lower surface of the light emitting element 200 may be d, and a horizontal distance from the upper edge of the opening 500 to a lower edge of the light emitting element 200 may be e. Furthermore, a distance from the upper edge of the light emitting element 200 to the lower edge of the opening 500 may be f. Such d may be greater than e, and f may be greater than d. Furthermore, e may be smaller than d. A ratio of e to f may be from 0.5 to 1. A ratio of d to f may be from 0.1 to 0.866.

Hereinafter, operations and effects of the light emitting device 10 according to the fourth embodiment of the present disclosure and the light emitting system 1 including the same will be described. The light emitting device 10 according to the fourth embodiment of the present disclosure may effectively block a pattern of the substrate 100 from being exposed.

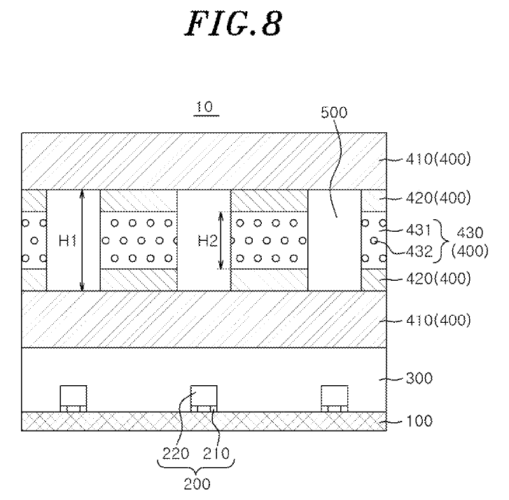

Hereinafter, a light emitting device 10 according to a fifth embodiment of the present disclosure and a light emitting system 1 including the same will be described with reference to FIG. 8. In describing the fifth embodiment, there is a difference in that the size of the plurality of openings 500 may be formed differently from the above-described third embodiment and fourth embodiment, and the description will focus on this difference.

Referring to FIG. 8, the aperture group layer 400 may include the opening 500, and a height H1 of the opening 500 may be greater than a height H2 of the aperture layer 430. Furthermore, the height H1 of the opening 500 may be greater than a height of the conductive layer 420. For example, the height H1 of the opening 500 may be equal to a sum of the height H2 of the aperture layer 430 and a height of the plurality of conductive layers 420.

A portion of a side surface of the opening 500 may be surrounded by the plurality of conductive layers 420. Therefore, when viewed from above, the plurality of conductive layers 420 may include the opening 500. The upper surface or the lower surface of the opening 500 may be covered by the support layer 410. Furthermore, when viewed from above, the light emitting element 200 may be located inside the opening 500.

Hereinafter, operations and effects of the light emitting device 10 according to the fifth embodiment of the present disclosure and the light emitting system 1 including the same will be described.

A current or voltage applied to the plurality of conductive layers 420 of the light emitting device 10 according to the fifth embodiment of the present disclosure is dispersed, such that a light blocking rate or light transmittance of the aperture group layer 400 may be formed uniformly.

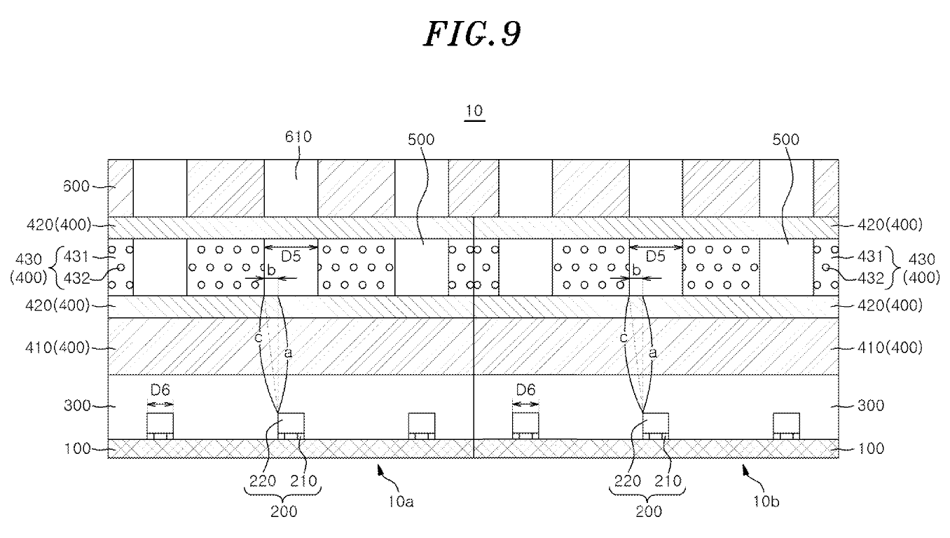

Hereinafter, a light emitting device 10 according to a sixth embodiment of the present disclosure and a light emitting system 1 including the same will be described with reference to FIG. 9. In describing the sixth embodiment, there is a difference in that the light emitting device 10 may further include a plurality of light emitting modules 10a and 10b and a cover layer 600, and the description will focus on this difference.

Each of the plurality of light emitting modules 10a and 10b may include the above-described substrate 100, light emitting element 200, molding layer 300, aperture group layer 400, and opening 500. The plurality of light emitting modules 10a and 10b may include a first light emitting module 10a and a second light emitting module 10b.

The first light emitting module 10a and the second light emitting module 10b may be connected to each other. In other words, the substrate 100 of the first light emitting module 10a may be connected to the substrate 100 of the second light emitting module 10b. The molding layer 300 of the first light emitting module 10a may be connected to the molding layer 300 of the second light emitting module 10b. Furthermore, the aperture group layer 400 of the first light emitting module 10a may be connected to the aperture group layer 400 of the second light emitting module 10b.

The cover layer 600 may cover the plurality of light emitting modules 10a and 10b. In other words, the cover layer 600 may be stacked on the aperture group layer 400 of the first light emitting module 10a and the aperture group layer 400 of the second light emitting module 10b. For example, the cover layer 600 may be a film or substrate made of polyethylene terephthalate (PET). The cover layer 600 may cover a connection portion between the first light emitting module 10a and the second light emitting module 10b.

A cover hole 610 may be formed in the cover layer 600. A plurality of cover holes 610 may be formed. The cover hole 610 may be disposed at a position corresponding to the opening 500 of the plurality of light emitting modules 10a and 10b. A width of the cover hole 610 may be equal to or smaller than the width D5 of the opening 500. Furthermore, the width of the cover hole 610 may be greater than the width D6 of the light emitting element 200. Light transmittance of this cover hole 610 may be equal to the light transmittance of the opening 500. A shape of the cover hole 610 may be circular or polygonal. Furthermore, a separation distance between some of the plurality of cover holes 610 may be different from a separation distance between others of the plurality of cover holes 610, but is not limited thereto.

Meanwhile, the cover layer 600 may be any one of the plurality of support layers 410 described above. In other words, the cover layer 600 may be one of the plurality of support layers 410 integrally formed while being stacked on each of the plurality of conductive layers 420 of the plurality of light emitting modules 10a and 10b. Such a cover layer 600 may cover a connection portion of the plurality of conductive layers 420 of the first light emitting module 10a and the plurality of conductive layers 420 of the second light emitting module 10b.

Hereinafter, operations and effects of the light emitting device 10 according to the sixth embodiment of the present disclosure and the light emitting system 1 including the same will be described.

The cover hole 610 of the light emitting device 10 according to the sixth embodiment of the present disclosure may increase visibility of light generated by the light emitting element 200.

Furthermore, the cover layer 600 of the light emitting device 10 may cover the connection portion between the first light emitting module 10a and the second light emitting module 10b.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

What is claimed is:

1. A light emitting device comprising:
a substrate;
a light emitting element disposed on the substrate to generate light;
a molding layer disposed on the substrate to cover the light emitting element; and
an aperture group layer disposed on the molding layer and emitting the light of the light emitting element to an outside,
wherein the aperture group layer includes:
a conductive layer applied with an electrical signal; and
an aperture layer configured to be in a first state of transmitting light when the electrical signal is applied to the conductive layer, and to be in a second state of scattering light when the electrical signal is not applied to the conductive layer, and
wherein luminous intensity of the light emitted from the aperture group layer in the first state is greater than luminous intensity of the light emitted from the aperture group layer in the second state.

2. The light emitting device of claim 1, wherein the luminous intensity of the light emitted from the aperture group layer in the second state is 50% or less of the luminous intensity of the light emitted from the aperture group layer in the first state.

3. The light emitting device of claim 1, wherein a color of the light emitted from the aperture group layer in the first state and a color of the light emitted from the aperture group layer in the second state are different from each other.

4. The light emitting device of claim 1, wherein the light emitting element comprises:
an element electrode layer electrically connected to the substrate; and
a light emitting layer emitting light when electricity is applied to the element electrode layer, and
wherein a number of conductive layers is greater than a number of element electrode layers.

5. The light emitting device of claim 1, wherein the substrate is configured to transmit light, and
wherein when the aperture layer is in the first state, a wavelength deviation between a peak wavelength of the light emitted from the aperture group layer and a peak wavelength of the light transmitted through the substrate is within 1%.

6. The light emitting device of claim 1, wherein the substrate is configured to transmit light, and
wherein when the aperture layer is in the second state, the luminous intensity of the light emitted from the aperture group layer is smaller than luminous intensity of the light transmitted through the substrate.

7. The light emitting device of claim 1, wherein the conductive layer includes a plurality of conductive layers,
wherien the aperture layer is disposed between the plurality of conductive layers,
wherein the aperture group layer further includes a plurality of support layers covering the plurality of conductive layers such that the plurality of conductive layers and the aperture layer are disposed inside, and
wherein one of the plurality of support layers is in contact with the molding layer.

8. The light emitting device of claim 7, wherein a thickness of each of the plurality of support layers is greater than a thickness of each of the plurality of conductive layers and a thickness of the aperture layer, and the thickness of the aperture layer is greater than the thickness of each of the plurality of conductive layers.

9. The light emitting device of claim 7, wherein a refractive index of the conductive layer is greater than a refractive index of the support layer.

10. The light emitting device of claim 1, wherein the aperture layer comprises:
a polymer layer supported by the conductive layer; and
a plurality of liquid crystal molecules disposed in the polymer layer,
wherein when the aperture layer is in the first state, a refractive index of the plurality of liquid crystal molecules is equal to the refractive index of the polymer layer, and
wherein when the aperture layer is in the second state, the refractive index of the plurality of liquid crystal molecules is different from the refractive index of the polymer layer.

11. The light emitting device of claim 10, wherein a refractive index of the conductive layer is greater than the refractive index of the polymer layer.

12. The light emitting device of claim 10, wherein the aperture layer further comprises:
a plurality of partition walls disposed in the polymer layer to partition the polymer layer into a plurality of polymer regions.

13. The light emitting device of claim 12, wherein the light emitting element includes a plurality of the light emitting elements, and the plurality of light emitting elements are disposed directly below the plurality of polymer regions.

14. The light emitting device of claim 12, wherein the light emitting element includes a plurality of the light emitting elements, and a separation distance between the plurality of partition walls is greater than a separation distance between the plurality of light emitting elements.

15. The light emitting device of claim 12, wherein the plurality of partition walls include:
a plurality of first partition walls extending in one direction and disposed to be spaced apart from each other in another direction intersecting the one direction; and
a plurality of second partition walls extending in the other direction and disposed to be spaced apart from each other in the one direction.

16. A light emitting device comprising:
a substrate;
a light emitting element disposed on the substrate to generate light;
a molding layer disposed on the substrate to cover the light emitting element; and
an aperture group layer stacked on the molding layer and emitting the light of the light emitting element,
wherein the aperture group layer includes:
a conductive layer applied with an electrical signal; and
an aperture layer configured to be in a first state of transmitting light when the electrical signal is applied to the conductive layer, and to be in a second state of scattering light when the electrical signal is not applied to the conductive layer, and
wherein brightness of the light emitted from the aperture group layer when the aperture layer is in the first state is greater than brightness of the light emitted from the aperture group layer when the aperture layer is in the second state.

17. The light emitting device of claim 16, wherein the substrate is configured to transmit light, and
wherein when the aperture layer is in the first state, a wavelength deviation between a peak wavelength of the light emitted from the aperture group layer and a peak wavelength of the light transmitted through the substrate is within 1%.

18. A light emitting device comprising:
a substrate;
a light emitting element disposed on the substrate to generate light;
a molding layer disposed on the substrate to cover the light emitting element; and
an aperture group layer stacked on the molding layer and emitting the light of the light emitting element,
wherein the aperture group layer includes:
a conductive layer applied with an electrical signal; and
an aperture layer configured to be in a first state of transmitting light when the electrical signal is applied to the conductive layer, and to be in a second state of scattering light when the electrical signal is not applied to the conductive layer, and
wherein a directivity angle of the light emitted from the aperture group layer when the aperture layer is in the first state is smaller than a directivity angle of the light emitted from the aperture group layer when the aperture layer is in the second state.

19. The light emitting device of claim 18, wherein the substrate is configured to transmit light, and
wherein when the aperture layer is in the first state, a wavelength deviation between a peak wavelength of the light emitted from the aperture group layer and a peak wavelength of the light transmitted through the substrate is within 1%.

20. The light emitting device of claim 19, wherein a color of the light emitted from the aperture group layer in the first state and a color of the light emitted from the aperture group layer in the second state are different from each other.
